(19) United States
(12) Patent Application Publication
(10) Pub. No.: US 2025/0356809 A1
(43) Pub. Date: Nov. 20, 2025

(54) DRIVING CIRCUIT

(71) Applicant: Samsung Display Co., Ltd., Yongin-si (KR)

(72) Inventors: Keukjin Jeong, Yongin-si (KR); Wongyun Kim, Yongin-si (KR); Min Kang, Yongin-si (KR)

(21) Appl. No.: 19/018,591

(22) Filed: Jan. 13, 2025

(30) Foreign Application Priority Data
May 16, 2024 (KR) 10-2024-0064135

(51) Int. Cl. G09G 3/3266; G11C 19/28

(52) U.S. Cl. CPC G09G 3/3266; G09G 2310/0286; G11C 19/28

(57) ABSTRACT

A driving circuit includes a first transistor connected between a first terminal to which a start signal is input and a first node and comprising a gate connected to a second node; a second transistor connected between a first clock terminal to which a first clock signal is input and the second node and comprising a gate connected to a second terminal to which a first voltage is supplied; a third transistor connected between the first node and the second node; and a fourth transistor connected between the first node and a gate of the third transistor and comprising a gate connected to the second node.

### CROSS-REFERENCE TO RELATED APPLICATION

The present application claims priority to and the benefit of Korean Patent Application No. 10-2024-0064135, filed on May 16, 2024, in the Korean Intellectual Property Office, the entire disclosure of which is incorporated herein by reference.

### BACKGROUND

### 1. Field

Aspects of embodiments according to the present disclosure relate to a display device.

### 2. Description of the Related Art

Display devices may include a pixel portion including a plurality of pixels, a gate driving circuit, and a data driving circuit. The gate driving circuit may include stages connected to gate lines and the stages may provide gate signals to the gate lines connected to the stages.

The above information disclosed in this Background section is only for enhancement of understanding of the background and therefore the information discussed in this Background section does not necessarily constitute prior art.

### SUMMARY

Aspects of embodiments according to the present disclosure relate to a display device, and for example, to a driving circuit configured to output a gate signal and a display device including the driving circuit.

Aspects of some embodiments according to the present disclosure include a gate driving circuit configured to have a relatively small size and relatively stably output gate signals and a display device including the gate driving circuit. Embodiments are not limited to the following description and other embodiments which are not mentioned in the following description may be clearly understood from the disclosure by one of ordinary skill in the art.

Additional aspects will be set forth in part in the description which follows and, in part, will be apparent from the description, or may be learned by practice of the presented embodiments of the disclosure.

According to one or more embodiments, a driving circuit includes a plurality of stages configured to output gate signals to pixels, wherein each of the plurality of stages includes a first transistor connected between a first terminal configured to receive a start signal and a first node and including a gate connected to a second node, a second transistor connected between a first clock terminal configured to receive a first clock signal and the second node and including a gate connected to a second terminal configured to receive a first voltage, a third transistor connected between the first node and the second node, a fourth transistor connected between a third node and a gate of the third transistor and including a gate connected to the second node, a fifth transistor connected between the first node and the third node and including a gate connected to a third terminal configured to receive a second voltage, and an output circuit configured to output the gate signal of a first level voltage or a second level voltage according to a voltage level of the second node and a voltage level of the third node.

According to one or more embodiments, the start signal may include an external signal or a gate signal output by a previous stage.

According to one or more embodiments, the first transistor and the fifth transistor may be P-type transistors and the second transistor, the third transistor, and the fourth transistor may be N-type transistors.

According to one or more embodiments, the output circuit may include a sixth transistor connected between the second terminal and an output terminal and including a gate connected to the second node, a seventh transistor connected between the output terminal and a second clock terminal configured to receive a second clock signal and including a gate connected to the third node, and a capacitor connected between the third node and the output terminal.

According to one or more embodiments, the sixth transistor and the seventh transistor may be P-type transistors.

According to one or more embodiments, the first clock signal and the second clock signal may be signals which alternate repeatedly the first level voltage and the second level voltage, the second clock signal being shifted by a half period with respect to the first clock signal.

According to one or more embodiments, in a first section to which the start signal of the second level voltage, the first clock signal of the second level voltage, and the second clock signal of the first level voltage are input, a voltage of the second node and a voltage of the third node may be the second level voltage, and the output terminal may be configured to output an output signal of the first level voltage through the turned-on sixth transistor and the turned-on seventh transistor.

According to one or more embodiments, in a second section which is subsequent to the first section and to which the start signal of the first level voltage, the first clock signal of the first level voltage, and the second clock signal of the first level voltage are input, the voltage of the second node may be the first level voltage, the voltage of the third node may be the second level voltage, and the output terminal may be configured to output the output signal of the first level voltage through the turned-on seventh transistor.

According to one or more embodiments, in a third section which is subsequent to the second section and to which the start signal of the first level voltage, the first clock signal of the first level voltage, and the second clock signal of the second level voltage are input, the voltage of the second node may be the first level voltage, the voltage of the third node may be the third level voltage lower than the second level voltage, and the output signal of the second level voltage may be output from the output terminal through the turned-on seventh transistor.

According to one or more embodiments, in a fourth section which is subsequent to the third section and to which the start signal of the first level voltage, the first clock signal of the first level voltage, and the second clock signal of the first level voltage are input, the voltage of the second node may be the first level voltage, the voltage of the third node may be the second level voltage, and the output signal of the first level voltage may be output from the output terminal through the turned-on seventh transistor.

According to one or more embodiments, in a fifth section which is subsequent to the fourth section and to which the start signal of the first level voltage, the first clock signal of the second level voltage, and the second clock signal of the first level voltage are input, the voltage of the second node may be the second level voltage, the voltage of the third node may be the first level voltage, and the output signal of the first level voltage may be output from the output terminal through the turned-on sixth transistor.

According to one or more embodiments, the first voltage may be the first level voltage and the second voltage may be the second level voltage.

According to one or more embodiments, a driving circuit includes a plurality of stages configured to output gate signals to pixels, wherein each of the plurality of stages includes a first transistor connected between a first terminal configured to receive a start signal and a first node and including a gate connected to a second node, a second transistor connected between a first clock terminal configured to receive a first clock signal and the second node and including a gate connected to a second terminal configured to receive a first voltage, a third transistor connected between the first node and the second node, a fourth transistor connected between the first node and a gate of the third transistor and including a gate connected to the second node, and an output circuit configured to output the gate signal of a first level voltage or a second level voltage according to a voltage level of the first node and a voltage level of the second node.

According to one or more embodiments, the output circuit may include a fifth transistor connected between the second terminal and an output terminal and including a gate connected to the second node, a sixth transistor connected between the output terminal and a second clock terminal configured to receive a second clock signal and including a gate connected to the first node, and a capacitor connected between the first node and the output terminal.

According to one or more embodiments, the first transistor, the fifth transistor, and the sixth transistor may be P-type transistors and the second transistor, the third transistor, and the fourth transistor may be N-type transistors.

According to one or more embodiments, in a first section to which the start signal of the second level voltage, the first clock signal of the second level voltage, and the second clock signal of the first level voltage are input, a voltage of the second node and a voltage of the third node may be the second level voltage, and an output signal of the first level voltage may be output from the output terminal through the turned-on fifth transistor and sixth transistor.

According to one or more embodiments, in a second section which is subsequent to the first section and to which the start signal of the first level voltage, the first clock signal of the first level voltage, and the second clock signal of the first level voltage are input, the voltage of the first node may be the second level voltage, the voltage of the second node may be the first level voltage, and the output signal of the first level voltage I may be output from the output terminal through the turned-on sixth transistor.

According to one or more embodiments, in a third section which is subsequent to the second section and to which the start signal of the first level voltage, the first clock signal of the first level voltage, and the second clock signal of the second level voltage are input, the voltage of the first node may be the third level voltage lower than the second level voltage, the voltage of the second node may be the first level voltage, and the output signal of the second level voltage may be output from the output terminal through the turned-on sixth transistor.

According to one or more embodiments, in a fourth section which is subsequent to the third section and to which the start signal of the first level voltage, the first clock signal of the first level voltage, and the second clock signal of the first level voltage are input, the voltage of the first node may be the second level voltage, the voltage of the second node may be the first level voltage, and the output signal of the first level voltage may be output from the output terminal through the turned-on sixth transistor.

According to one or more embodiments, in a fifth section which is subsequent to the fourth section and to which the start signal of the first level voltage, the first clock signal of the second level voltage, and the second clock signal of the first level voltage are input, the voltage of the first node may be the first level voltage, the voltage of the second node may be the second level voltage, and the output signal of the first level voltage may be output from the output terminal through the turned-on fifth transistor.

According to one or more embodiments, an electronic device comprising a controller configured to receive a signal from a processor and output a driving control signal, and a driving circuit configured to receive the driving control signal, the driving circuit comprising a plurality of stages configured to output gate signals to pixels, wherein each of the plurality of stages includes a first transistor connected between a first terminal to which a start signal is input and a first node and including a gate connected to a second node, a second transistor connected between a first clock terminal to which a first clock signal is input and the second node and including a gate connected to a second terminal to which a first voltage is supplied, a third transistor connected between the first node and the second node, a fourth transistor connected between a third node and a gate of the third transistor and including a gate connected to the second node, a fifth transistor connected between the first node and the third node and including a gate connected to a third terminal to which a second voltage is supplied, and an output circuit outputting the gate signal of a first level voltage or a second level voltage according to a voltage level of the second node and a voltage level of the third node.

### BRIEF DESCRIPTION OF THE DRAWINGS

The above and other aspects, features, and characteristics of certain embodiments of the disclosure will be more apparent from the following description taken in conjunction with the accompanying drawings, in which:

FIGS. 1A and 1B are schematic views of a display device according to some embodiments;

FIG. 2 is a schematic view of a display device according to some embodiments;

FIG. 3 is a schematic view of a gate driving circuit according to some embodiments;

FIG. 4 is a schematic view of input/output signals of a driving circuit according to some embodiments;

FIG. 5 is a circuit diagram showing an example of the stage included in the gate driving circuit of FIG. 3;

FIG. 6 is a circuit diagram showing an example of the stage included in the gate driving circuit of FIG. 3; and

FIG. 7 is a timing diagram illustrating a driving of the stage of FIGS. 5 and 6, according to some embodiments.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b, or c” indicates only a, only b, only c, both a and b, both a and c, both b and c, all of a, b, and c, or variations thereof.

Because the disclosure may have diverse modified embodiments, aspects of various embodiments are illustrated in the drawings and are described in the detailed description. Characteristics of embodiments according to the present disclosure, and a method of accomplishing these will be more apparent when referring to disclosed embodiments described with reference to the drawings. The disclosure may, however, be embodied in many different forms and should not be construed as limited to the embodiments set forth herein.

In the embodiments, the terms “first” and “second” are not used in a limited sense and are used to distinguish one element from another element.

It will be understood that an expression used in the singular encompasses the expression of the plural, unless it has a clearly different meaning in the context.

It will be understood that the terms “comprises” and/or “comprising” used herein specify the presence of stated features or elements, but do not preclude the presence or addition of one or more other features or elements.

It will be understood that when a layer, region, or element is referred to as being formed “on” another layer, area, or element, it can be directly or indirectly formed on the other layer, region, or element. That is, for example, intervening layers, regions, or elements may be present.

In the drawings, for convenience of description, sizes of elements may be exaggerated or reduced. For example, because sizes and thicknesses of elements in the drawings are arbitrarily illustrated for convenience of explanation, the disclosure is not limited thereto.

In this specification, the expression “A and/or B” may indicate A, B, or A and B. Also, the expression “at least one of A and B” may indicate A, B, or A and B.

In the following embodiments, when X and Y are connected to each other, X and Y may be electrically, functionally, or physically connected to each other. In addition, when X and Y are connected to each other, X and Y may be directly connected to each other or X and Y may be indirectly connected to each with other components arranged therebetween. Here, X and Y may be elements (e.g., devices, components, circuits, wiring, electrodes, terminals, membranes, layers, regions, etc.).

For example, if X and Y are electrically connected to each other, X and Y may be directly and electrically connected to each other and/or X and Y may be indirectly and electrically connected to each other with other elements arranged therebetween. If X and Y are indirectly and electrically connected to each other, at least one element that allows an electrical connection between X and Y (e.g., a switch, a transistor, a capacity element, an inductor, a resistance element, a diode, etc.) may be connected between X and Y. Thus, embodiments are not limited to a set or predetermined connection relation, for example, a connection relation shown in the drawing or the detailed description, but may also include connection relations other than those shown in the drawing or the detailed description.

In the following embodiments, the expressions “on” and “off” used to describe the state of an element refer to an active state or an inactivated state of the element, respectively. The expressions “on” and “off” used to describe signals received by the element refer to a signal activating the element or a signal inactivating the element, respectively. The element may be activated by a high-level voltage or a low-level voltage. For example, a P-type transistor (a P-channel transistor) may be activated by a low-level voltage and an N-type transistor (an N-channel transistor) may be activated by a high-level voltage. Therefore, it should be understood that the “on” voltages of the P-type transistors and the N-type transistor are opposite (low and high) voltage levels from each other. Hereinafter, the voltage for activating (turning on) the transistor is referred to as a gate-on voltage and the voltage for inactivating (turning off) the transistor is referred to as a gate-off voltage.

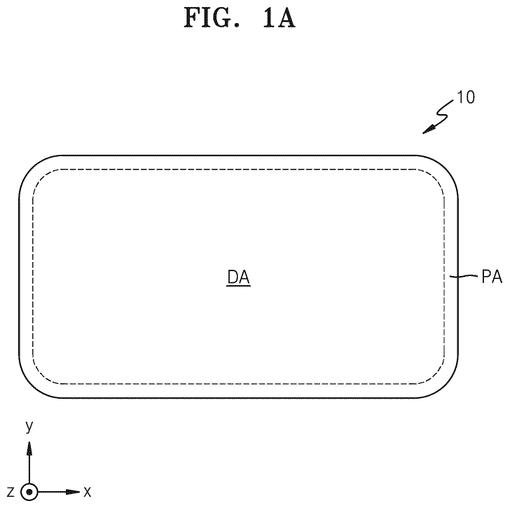

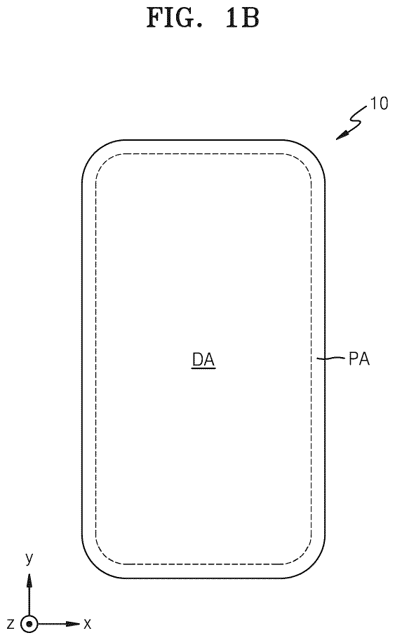

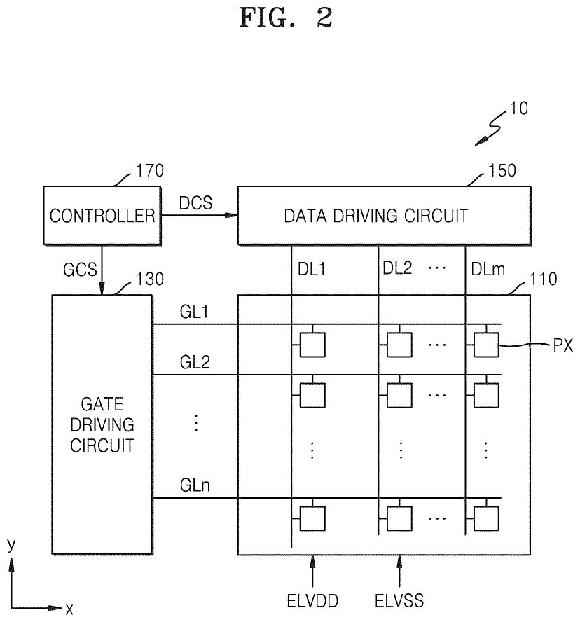

FIGS. 1A and 1B are schematic views of a display device according to some embodiments. FIG. 2 is a schematic view of a display device according to some embodiments.

Referring to FIGS. 1A and 1B, the display device 10 may include a display area DA for displaying images and a peripheral area PA outside (e.g., in a periphery or outside a footprint of) the display area DA. The display area DA may be entirely surrounded by the peripheral area PA.

In a plan view, the display area DA may have a rectangular shape. In some embodiments, the display area DA may have a polygonal shape such as a triangular, pentagonal, or hexagonal shape or may have a circular, elliptical, or atypical shape. A corner of an edge of the display area DA may be rounded. According to some embodiments, the display device 10 may have a display area DA having a greater length in the x direction than in the y direction, as shown in FIG. 1A. In some embodiments, the display device 10 may have a display area DA having a greater length in the y direction than in the x direction, as shown in FIG. 1B.

The display device 10 according to some embodiments may be an organic light-emitting display, an inorganic light-emitting display (or an inorganic EL display), or a quantum dot light-emitting display.

Referring to FIG. 2, the display device 10 according to some embodiments may include a pixel area 110, a gate driving circuit 130, a data driving circuit 150, and a controller 170.

A plurality of pixels PX and signal lines configured to input electrical signals to the plurality of pixels PX may be arranged in the pixel area 110.

The plurality of pixels PX may be repeatedly arranged in the first direction (the x direction, the row direction) and the second direction (the y direction, the column direction). The plurality of pixels PX may be arranged in various forms such as a striped arrangement, a pentile arrangement, a diamond arrangement, a mosaic arrangement, etc. to display an image. Each of the plurality of pixels PX may include an organic light-emitting diode as a display element, and the organic light-emitting diode may be connected to the pixel circuit. The pixel circuit may include a plurality of transistors and at least one capacitor.

According to some embodiments, the plurality of transistors included in the pixel area 110 may be P-type silicon transistors. The silicon transistor may include a silicon semiconductor and the silicon semiconductor may include amorphous silicon, poly silicon, etc. For example, the silicon transistor may be a low temperature polycrystalline silicon (LTPS) thin-film transistor.

According to some embodiments, the plurality of transistors included in the pixel circuit may be N-type oxide transistors. The oxide transistor may include an oxide semiconductor and the oxide semiconductor may include a Zn oxide, an In—Zn oxide, a Ga—In—Zn oxide, etc. as Zn oxide materials. According to some embodiments, the oxide semiconductor may be an IGZO (In—Ga—Zn—O) semiconductor. According to some embodiments, the oxide semiconductor may be an IGZO (In—Ga—Zn—O) semiconductor. For example, the oxide transistor may be a low temperature polycrystalline oxide (LTPO) thin-film transistor. According to some embodiments, some of the plurality of transistors included in the pixel circuit may be P-type silicon transistors and others may be N-type oxide transistors.

The signal lines configured to input electrical signals to the plurality of pixels PX may include a plurality of gate lines GL1 to GLn extending in the first direction and a plurality of data lines DL1 to DLm extending in the second direction. The plurality of gate lines GL1 to GLn may be arranged apart from each other in the second direction and may be configured to transmit gate signals to the pixels PX. The plurality of data lines DL1 to DLm may be arranged apart from each other in the first direction and may be configured to transmit data signals to the pixels PX. Each of the plurality of pixels PX may be connected to at least one corresponding gate line among the plurality of gate lines GL1 to GLn and a corresponding data line among the plurality of data lines DL1 to DLm. The pixel PX may receive a data signal from the corresponding data line when the gate signal is supplied through the corresponding gate line.

The gate driving circuit 130 may be connected to the plurality of gate lines GL1 to GLn, may generate gate signals in response to a gate driving control signal GCS from the controller 170, and sequentially supply the gate signals to the gate lines GL1 to GLn. The gate lines GL1 to GLn may be connected to the gate of the transistor included in the pixel PX and the gate signal may be a gate control signal controlling the turn-on and turn-off of the transistor to which the gate line is connected. The gate signal may include a gate-on voltage that may turn on the transistor and a gate-off voltage that may turn off the transistor.

The gate driving circuit 130 may include a shift register that sequentially generates and outputs the gate signals.

The data driving circuit 150 may be connected to the plurality of data lines DL1 to DLm and may supply the data signals to the data lines DL1 to DLm in response to a data driving control signal DCS from the controller 170. The data signals supplied to the data lines DL1 to DLm may be supplied to the pixels PX to which the gate signals are supplied.

If the display device is an organic light-emitting display device, a first power voltage ELVDD and a second power voltage ELVSS may be supplied to the pixels PX of the pixel area 110. The first power voltage ELVDD may be a high-level voltage supplied to a terminal of the driving transistor included in each pixel PX. The second power voltage ELVSS may be a low-level voltage provided to the second electrode (opposite electrode or cathode) of the organic light-emitting diode connected to the other terminal of the driving transistor. The first power voltage ELVDD and the second power voltage ELVSS may be driving voltages for the plurality of pixels PX to emit light.

The controller 170 may generate a gate driving control signal GCS and a data driving control signal DCS based on the signals input from the outside (for example, a processor of an electronic device). The controller 170 may supply the gate driving control signal GCS to the gate driving circuit 130 and the data driving control signal DCS to the data driving circuit 150.

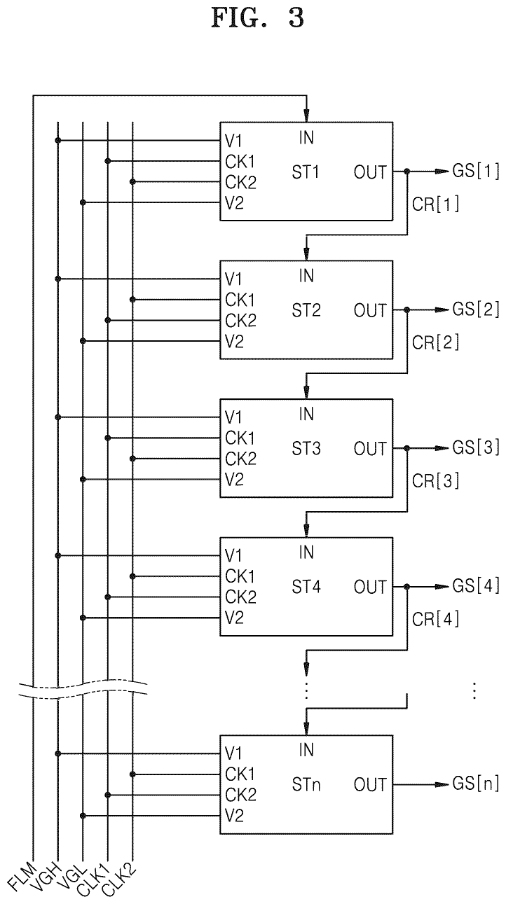

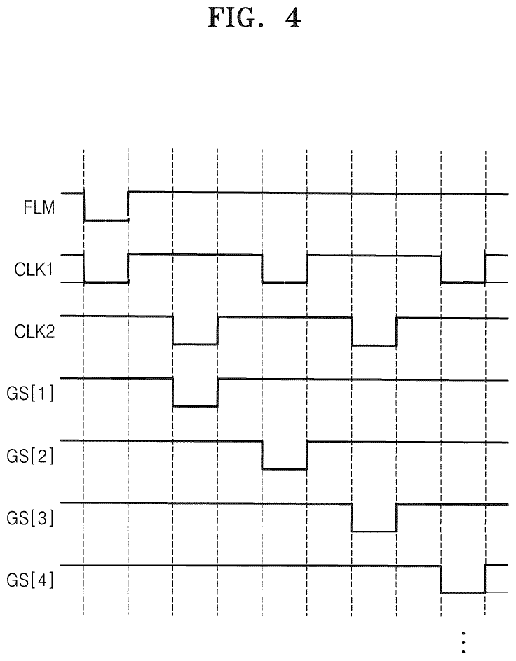

FIG. 3 is a schematic view of the gate driving circuit according to some embodiments and FIG. 4 is a schematic view of input/output signals of the driving circuit according to some embodiments.

Referring to FIG. 3, the gate driving circuit 130 may include a plurality of stages ST1 and STn. The plurality of stages ST1 to STn may sequentially output gate signals GS1 or GSn to the gate lines. The number of stages included in the gate driving circuit 130 may be variously modified depending on the number of rows (horizontal lines) included in the pixel area 110.

Each stage ST1 to STn may be connected to the gate line arranged in the corresponding row of the pixel area 110. Each of the stages ST1 to STn may receive at least one clock signal and at least one voltage signal, may generate the gate signal GS, and may output the gate signal GS to the gate line GL connected to each of the stages ST1 to STn. In other words, each of the stages ST1 to STn may supply the gate signal GS to the gate line GL included in the corresponding row.

Each of the plurality of stages ST1 to STn may output gate signals GS[1], GS[2], GS[3], GS[4], . . . , GS[n] in response to a start signal. For example, an nth stage STn may output an nth gate signal GS[n] to the nth gate line. An external signal FLM, which is a start signal controlling the timing of the first gate signal GS[1], may be supplied to the first stage ST1.

Each of the stages ST1 to STn may include a plurality of terminals to/from which a plurality of signals are input/output. The plurality of signals may include clock signals and voltage signals. The plurality of terminals may include an input terminal IN, a first voltage input terminal V1, a second voltage input terminal V2, a first clock terminal CK1, a second clock terminal CK2, and an output terminal OUT.

The start signal may be input (supplied) to the input terminal IN. The start signal may be an external signal FLM or a carry signal CR[1], CR[2], CR[3], CR[4], . . . , CR[n-1]. According to some embodiments, the carry signal CR[1], CR[2], CR[3], CR[4], . . . , CR[n-1]) may be a gate signal output by a previous stage (hereinafter referred to as a previous gate signal). The external signal FLM is input to the input terminal IN of the first stage ST1 as a start signal and the previous gate signal is input to the input terminal IN of each of the second to nth stages ST2 to STn. The previous stage may be arranged at least one stage before a current stage. FIG. 3 shows an example in which the previous stage is a stage arranged right before the current stage. For example, a third gate signal GS[3] output from a third stage ST3 may be input to the input terminal IN of a fourth stage ST4 as a carry signal CR[3].

A first voltage VGH may be input to the first voltage input terminal V1 and a second voltage VGL may be input to the second voltage input terminal V2. The second voltage VGL may be less than the first voltage VGH. The first voltage VGH and the second voltage VGL, as global signals, may be input from the controller 170 shown in FIG. 2 and/or a power supply circuit.

A first clock signal CLK1 or a second clock signal CLK2 may be input to the first clock terminal CK1 and the second clock terminal CK2. The first clock signal CLK1 and the second clock signal CLK2 may be input alternately to the first clock terminals CK1 of the stages ST1 to STn. The second clock signal CLK2 and the first clock signal CLK1 may be input alternately to the second clock terminals CK2 of the stages ST1 to

STn. For example, the first clock signal CLK1 and the second clock signal CLK2 may be respectively input to the first clock terminal CK1 and the second clock terminal CK2 of odd numbered stages ST1, ST3, . . . . The first clock signal CLK1 and the second clock signal CLK2 may be respectively input to the first clock terminal CK1 and the second clock terminal CK2 of even numbered stages ST2, ST4, . . .

As shown in FIG. 3, the first clock signal CLK1 and the second clock signal CLK2 may be square wave signals repeatedly having high-level voltages and low-level voltages. According to some embodiments, the first clock signal CLK1 and the second clock signal CLK2 may be square wave signals repeatedly having the first voltage VGH and the second voltage VGL. The first clock signal CLK1 and the second clock signal CLK2 may have the same waveform and may be phase-shifted signals. For example, the second clock signal CLK2 may have the same waveform as the first clock signal CLK1 and may be input with phase-shifted in certain interval (phase delayed). The second clock signal CLK2 may be shifted by a half period with respect to the first clock signal CLK1. A period of the first clock signal CLK1 and the second clock signal CLK2 may be approximately two horizontal line time (2H).

As shown in FIG. 4, a duration in which a high-level voltage is maintained may be greater than a duration in which the low-level voltage is maintained in a period of the first clock signal CLK1 and the second clock signal CLK2. Embodiments of the disclosure are not limited thereto. For example, a duration in which a high-level voltage is maintained may be the same as a duration in which the low-level voltage is maintained in a period of the first clock signal CLK1 and the second clock signal CLK2.

The gate signal may be output from the output terminal OUT. As shown in FIG. 4, the gate signals GS[1], GS[2], GS[3], GS[4], . . . , GS[n] output from the output terminals OUT of the stages ST1 to STn may be sequentially shifted by an interval (e.g., a set or predetermined interval). Each gate signal may be supplied to a pixel through a corresponding output line, for example, a gate line. According to some embodiments, the high-level voltage and the low-level voltage of the gate signals GS[1], GS[2], GS[3], GS[4], . . . , GS[n]) may be the first voltage VGH and second voltage VGL, respectively.

According to some embodiments, the low-level voltage of the gate signals GS[1], GS[2], GS[3], GS[4], . . . , GS[n] may turn on the P-type transistor of the pixel circuit. The stages ST1 to STn may output gate signals GS[1], GS[2], GS[3], GS[4], . . . , GS[n] with low-level voltages for a half of a horizontal line time (½H). The gate signals GS[1], GS[2], GS[3], GS[4], . . . , GS[n] with low-level voltages may be shifted by 1H and be output sequentially. The gate signals GS[1], GS[2], GS[3], GS[4], . . . , GS[n] with low-level voltages may be shifted by 1H from the start signal and be output.

Hereinafter, a kth stage (STK, k is a natural number) corresponding to a k row of the pixel area 110 is described as an example. The stage STK may receive a k−1^{th} gate signal GS[k−1] (hereinafter, also referred to as a previous gate signal GS[k−1]), as a start signal, from the previous stage, that is, the k−1^{th} stage, may output a kth gate signal GS[k] to the gate line of the kth row, and output the kth gate signal GS[k], as a carry signal, to the next stage, that is, the k+1^{th} stage.

In the odd numbered stage, the first clock terminal CK1 may receive the first clock signal CLK1 and the second clock terminal CK2 may receive the second clock signal CLK2. In the even numbered stage, the first clock terminal CK1 may receive the second clock signal CLK2 and the second clock terminal CK2 may receive the first clock signal CLK1. Hereinafter, for convenience of description, the kth stage STK (hereinafter referred to as the stage STK) is an odd numbered stage, the first clock signal CLK1 is input to the first clock terminal CK1, and the second clock signal CLK2 is input to the second clock terminal CK2. When k is 1, the first stage ST1 may receive an external signal FLM as a start signal through the input terminal IN.

Hereinafter, the first voltage VGH may be a high-level voltage and the second voltage VGL may be a low-level voltage. In addition, a high-level voltage may be represented by a first level voltage and a low-level voltage may be represented by the second level voltage level.

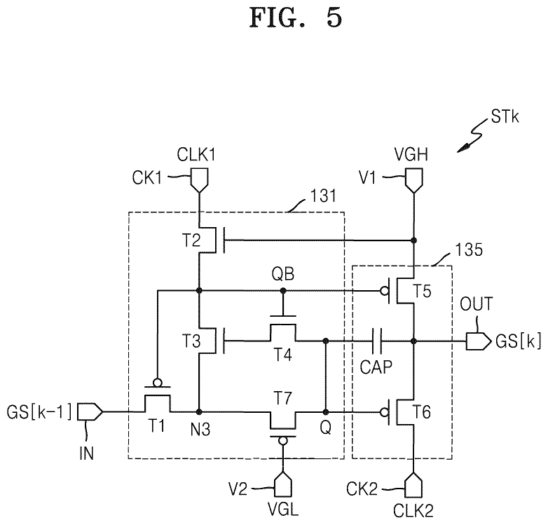

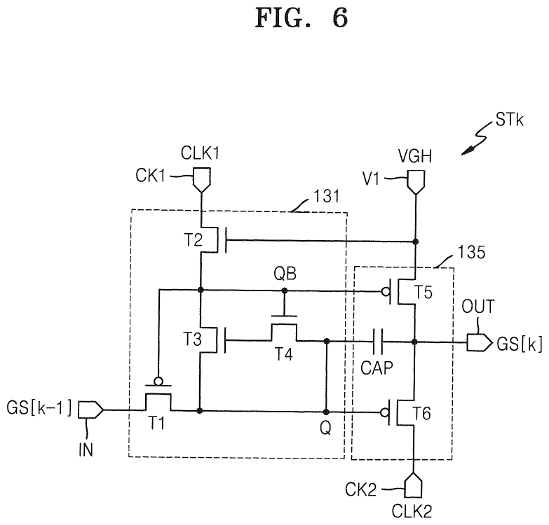

FIGS. 5 and 6 are circuit diagrams showing examples of the stage included in the gate driving circuit of FIG. 3. Although FIGS. 5 and 6 illustrate various components in stages according to some embodiments, embodiments according to the present disclosure are not limited thereto, and according to various embodiments, the stages may include additional components or fewer components without departing from the spirit and scope of embodiments according to the present disclosure.

Referring to FIGS. 5 and 6, the stage STK may include a control circuit 131 and an output circuit 135. Each of the control circuit 131 and the output circuit 135 may include at least one transistor. At least one transistor may include an N-type transistor and/or a P-type transistor. For example, the first transistor T1, the fifth transistor T5, the sixth transistor T6, and the seventh transistor T7 may be P-type transistors and the second transistor T2, the third transistor T3, and the fourth transistor T4 may be N-type transistors. The gate-on voltage of the P-type transistor may be a low-level voltage and the gate-off voltage of the P-type transistor may be a high-level voltage. The gate-on voltage of the N-type transistor may be a high-level voltage and the gate-off voltage of the N-type transistor may be a low-level voltage.

The control circuit 131 may control the voltage of a first node Q and a second node QB in response to the signals input to the input terminal IN and the first clock terminal CK1. For example, the control circuit 131 may control the voltage of the first node Q and the second node QB in response to the start signal (e.g., the external signal FLM (FIG. 3) or a carry signal CR (FIG. 3)), the first clock signal CLK1, or the second clock signal CLK2. According to some embodiments, the carry signal CR may be a previous gate signal GS[k−1]. Referring to FIG. 5, according to some embodiments, the control circuit 131 may include the first to fourth transistors T1 to T4 and the seventh transistor T7. Referring to FIG. 6, according to some embodiments, the control circuit 131 may include only the first to fourth transistors T1 to T4. Hereinafter, the connection and operation of each transistor in the control circuit 131 shown in FIG. 5 are described.

The first transistor T1 may be connected between the input terminal IN and the third node N3. The gate of the first transistor T1 may be connected to the second node QB. The first transistor T1 may be turned on when the first clock signal CLK1 input to the first clock terminal CK1 has a low level and may be configured to transmit the start signal to the third node N3. Referring to FIG. 6, according to some embodiments, the control circuit 131 may not include the seventh transistor T7, in which case the first node Q may be the same node as the third node N3.

The second transistor T2 may be connected between the first clock terminal CK1 to which the first clock signal CLK1 is input and the second node QB. The gate of the second transistor T2 may be connected to the first voltage input terminal V1 supplying the first voltage VGH. The second transistor T2 may be turned on by the first voltage VGH input to the first voltage input terminal V1 and may be configured to transmit the first clock signal CLK1 input through the first clock terminal CK1 to the second node QB. The second transistor T2 may always be turned on. A voltage variation range of the second node QB may be relatively reduced more than a voltage variation range of the clock signal through the second transistor T2. Accordingly, a variation range of the voltage supplied to the gate of the first transistor T1 and the fifth transistor T5 may be relatively reduced, and power consumption for on-off switching of the first transistor T1 and the fifth transistor T5 may be relatively reduced.

The third transistor T3 may be connected between the second node QB and the third node N3. The gate of the third transistor T3 may be connected to a terminal of the fourth transistor T4 described below.

The fourth transistor T4 may be connected between the gate of the third transistor T3 and the first node Q. The gate of the fourth transistor T4 may be connected to the second node QB. The fourth transistor T4 may be turned on when the first clock signal CLK1 input to the first clock terminal CK1 has a high level.

The seventh transistor T7 may be connected between the first node Q and the third node N3. The gate of the seventh transistor T7 may be connected to the second voltage input terminal V2 supplying the second voltage VGL. By using the second voltage VGL which is a constant voltage instead of the carry signal as the low-level voltage supplied to the gate of the seventh transistor T7, the seventh transistor T7 may always be turned on regardless of the defect, etc. of the carry signal. A voltage variation range of the third node N3 may be relatively reduced more than a voltage variation range of the first node Q through the seventh transistor T7. For example, the first transistor T1 and the seventh transistor T7 share the stress caused by a multi-stage voltage variation of the first node Q and thus the stress of the first transistor T1 may be relieved compared to when the seventh transistor T7 is omitted and only the first transistor T1 is included in the stage (FIG. 6). In addition, when the first transistor T1 is turned off, a line voltage drop between the input terminal IN and the first node Q may be prevented or relatively reduced by the seventh transistor T7.

The output circuit 135 may be connected between the first voltage input terminal V1 and the second clock terminal CK2. The output circuit 135 may output the gate signal GS[k] of the first level voltage or the second level voltage according to the voltage level of the first node Q and the second node QB. The output circuit 135 may include the fifth transistor T5 and the sixth transistor T6. The output circuit 135 may further include a capacitor CAP.

The fifth transistor T5 may be connected between the first voltage input terminal V1 and the output terminal OUT. The gate of the fifth transistor T5 may be connected to the second node QB. The fifth transistor T5 may be a pull-up transistor configured to transmit a high-level voltage to the output terminal OUT. The fifth transistor T5 may be turned on when the second node QB has a low level and may be configured to transmit the first voltage VGH of the high-level voltage input to the first voltage input terminal V1 to the output terminal OUT.

The sixth transistor T6 may be connected between the output terminal OUT and the second clock terminal CK2. The gate of the sixth transistor T6 may be connected to the first node Q. The sixth transistor T6 may be turned on when the first node Q has a low level and may be configured to transmit the second clock signal CLK2 input to the second clock terminal CK2 to the output terminal OUT. When the second clock signal CLK2 is a low-level voltage, the sixth transistor T6 may act as a pull-down transistor configured to transmit the low-level voltage of the second clock signal CLK2 to the output terminal OUT.

The capacitor CAP may be connected between the first node Q and the output terminal OUT. The voltage of the first node Q may be maintained by the capacitor CAP when the first transistor T1 is turned off. When the voltage level in the output terminal OUT is transitioned from a high level to a low level, the low-level voltage of the first node Q may be changed to an even lower voltage level by the capacitor CAP.

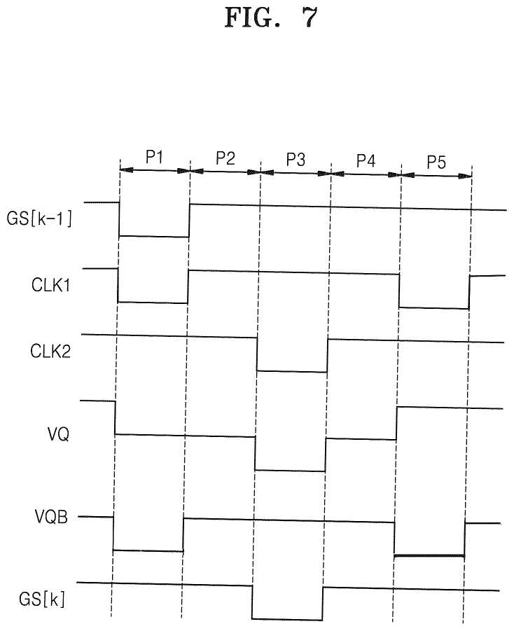

FIG. 7 is a timing diagram illustrating the driving of the stage of FIGS. 5 and 6 according to some embodiments.

Hereinafter, with reference to FIG. 7, the operation of the stage STK shown in FIGS. 5 and 6 will be described. In FIG. 7, the previous gate signal GS[k−1], the first clock signal CLK1, the second clock signal CLK2, the voltage VQ of the first node Q, and the voltage VQB of the second node QB are illustrated as the start signal, and the gate signal GS[k] is illustrated as the output signal.

In a first section P1, a low-level previous gate signal GS[k−1] may be supplied from the previous stage to the input terminal IN, the low-level first clock signal CLK1 may be supplied to the first clock terminal CK1, and the high-level second clock signal CLK2 may be supplied to the second clock terminal CK2.

The first transistor T1 may be turned on by the first clock signal CLK1 of a low level. The second transistor T2 may be turned on by the first voltage VGH of a high level. The seventh transistor T7 may be turned on by the second voltage VGL of a low level.

The low-level previous gate signal GS[k−1] may be transmitted to the first node Q through the turned-on first transistor T1 and the seventh transistor T7, and the voltage of the first node Q may be a low-level voltage. Accordingly, the sixth transistor T6 may be turned on and the high-level second clock signal CLK2 may be transmitted to the output terminal OUT.

The low-level first clock signal CLK1 may be transmitted to the second node QB by the turned-on second transistor T2, and the voltage of the second node QB may be a low-level voltage. Accordingly, the fifth transistor T5 may be turned on and the first voltage VGH may be transmitted to the output terminal OUT. In this case, the fourth transistor T4 in which the gate is connected to the second node QB may be turned off and the third transistor T3 may be turned on by the high-level voltage supplied to the gate of the third transistor T3 in a previous section.

Thus, a high-level gate signal GS[k] may be output from the output terminal OUT. A voltage difference between the output terminal OUT and the first node Q may be stored in the capacitor CAP.

In a second section P2, a high-level previous gate signal GS[k−1] may be supplied to the input terminal IN, the high-level first clock signal CLK1 may be supplied to the first clock terminal CK1, and the high-level second clock signal CLK2 may be supplied to the second clock terminal CK2.

The second transistor T2 may be turned on by the first voltage VGH of a high level. The high-level first clock signal CLK1 may be transmitted to the second node QB by the turned-on second transistor T2, and the voltage of the second node QB may be a high-level voltage. Accordingly, the first transistor T1 and the fifth transistor T5 may be turned off and the fourth transistor T4 may be turned on. The third transistor T3 may be turned off by receiving the low-level voltage of the first node Q.

Because the low-level voltage of the first node Q in the first section P1 may be maintained by the capacitor CAP, the turned-on state of the sixth transistor T6 may be maintained, and accordingly, the high-level second clock signal CLK2 may be transmitted to the output terminal OUT. Thus, the high-level gate signal GS[k] may be output from the output terminal OUT. Because the voltage of the first node Q has a low level, the third transistor T3 may be turned off.

In a third section P3, the high-level previous gate signal GS[k−1] may be supplied to the input terminal IN, the high-level first clock signal CLK1 may be supplied to the first clock terminal CK1, and the low-level second clock signal CLK2 may be supplied to the second clock terminal CK2.

The second transistor T2 may be turned on by the first voltage VGH of a high level. The high-level first clock signal CLK1 may be transmitted to the second node QB by the turned-on second transistor T2, and the voltage of the second node QB may be a high-level voltage. Accordingly, the first transistor T1 and the fifth transistor T5 may be turned off and the fourth transistor T4 may be turned on. The third transistor T3 may be turned off by receiving the low-level voltage of the first node Q.

The low-level voltage of the first node Q in the second section P2 may be maintained by the capacitor CAP and the low-level second clock signal CLK2 may be transmitted to the output terminal OUT through the sixth transistor T6 of which the turned-on state is maintained. Thus, the low-level gate signal GS[k] may be output from the output terminal OUT. As the voltage of the output terminal OUT is dropped from a high level to a low level, the voltage of the first node Q may be dropped to a voltage level (a third voltage level) lower than the voltage level (the second voltage level) of the first node Q in the second section P2. In this case, a voltage variation range of the third node N3 may be less than a voltage variation range of the first node Q due to the seventh transistor T7.

In a fourth section P4, the high-level previous gate signal GS[k−1] may be supplied to the input terminal IN, the high-level first clock signal CLK1 may be supplied to the first clock terminal CK1, and the high-level second clock signal CLK2 may be supplied to the second clock terminal CK2.

The second transistor T2 may be turned on by the first voltage VGH of a high level. The high-level first clock signal CLK1 may be transmitted to the second node QB by the turned-on second transistor T2, and the voltage of the second node QB may be a high-level voltage. Accordingly, the first transistor T1 and the fifth transistor T5 may be turned off and the fourth transistor T4 may be turned on. The third transistor T3 may be turned off by receiving the low-level voltage of the first node Q.

The low-level voltage of the first node Q in the third section P3 may be maintained by the capacitor CAP and the high-level second clock signal CLK2 may be transmitted to the output terminal OUT through the sixth transistor T6 of which the turned-on state is maintained. Thus, a high-level gate signal GS[k] may be output from the output terminal OUT. As the voltage of the output terminal OUT is increased from the low level to the high level, the coupling of the capacitor CAP may cause the voltage of the first node Q to be increased to a low level (e.g., the voltage level in approximately the second section P2) higher than the voltage level in the third section P3. According to some embodiments, the voltage of the second node QB may be increased according to the increase of the voltage of the first node Q through a capacitor formed between the second node QB to which the gate of the fourth transistor T4 is connected and the first node Q to which a terminal of the fourth transistor T4 is connected.

In a fifth section P5, the high-level previous gate signal GS[k−1] may be supplied to the input terminal IN, the low-level first clock signal CLK1 may be supplied to the first clock terminal CK1, and the high-level second clock signal CLK2 may be supplied to the second clock terminal CK2.

The second transistor T2 may be turned on by the first voltage VGH of a high level. The seventh transistor T7 may be turned on by the second voltage VGH of a low level.

The low-level first clock signal CLK1 may be transmitted to the second node QB by the turned-on second transistor T2, and the voltage of the second node QB may be a low-level voltage. Accordingly, the first transistor T1 and the fifth transistor T5 may be turned on, the fourth transistor T4 may be turned off, and the turned-off state of the third transistor T3 may be maintained. The high-level first voltage VGH may be transmitted to the output terminal OUT by the turned-on fifth transistor T5. Thus, a high-level gate signal GS[k] may be output from the output terminal OUT.

The high-level previous gate signal GS[k−1] may be transmitted to the first node Q through the turned-on first transistor T1 and the seventh transistor T7, and the voltage of the first node Q may be a high-level voltage. Accordingly, the sixth transistor T6 may be turned off.

In the second section P2 to the fourth section P4, the first transistor T1 and the third transistor T3 may be turned off. In this case, a capacitor formed by a voltage difference between the gate and a terminal (a source or drain) of the first transistor T1 may be a parallel connection between a capacitor formed between the gate and a terminal of the first transistor T1 and a capacitor formed between terminals (a source and drain) of the third transistor T3. The stress of the first transistor T1 may be relatively reduced by the first transistor T1 and the third transistor T3 sharing a load caused by a voltage difference between the gate and a terminal of the first transistor T1.

In the fifth section P5, when the first transistor T1 is turned on, the third transistor T3 is turned off, thereby preventing or relatively reducing instances of a short circuit between the first node Q in a high-level voltage state and the second node QB in a low-level voltage state.

According to one or more embodiments, a driving circuit and a display device including the driving circuit may be provided, wherein the driving circuit includes a small number of transistors and capacitors to minimize or relatively reduce a dead space and relatively stably output gate signals. In addition, by not directly transmitting the clock signal to the first node Q and the second node QB, the power consumption in the output circuit 135 may be relatively reduced.

The gate driving circuit according to some embodiments may include a small number of circuit elements, thereby having a relatively reduced non-display area and relatively stably outputting a gate signal, and the display device may include the gate driving circuit.

An electronic device according to an embodiment may output various information through the display device 10 under control of an operating system. When a processor executes an application stored in a memory, the display device 10 may provide application information to a user through a display panel.

The display device 10 may be used as a display screen of not only a portable electronic device, such as a mobile phone, a smartphone, a tablet personal computer (PC), a mobile communication terminal, an electronic notebook, an e-book, a portable multimedia player (PMP), a navigation system, or an ultra-mobile PC (UMPC), but also any of various products, such as a television, a computer device, a laptop, a monitor, a billboard, or the Internet of things (IoT). Also, the display device 10 according to an embodiment may be used in a wearable device such as a smart watch, a watch phone, a glasses-type display, or a head-mounted display (HMD). Also, the display device 10 according to an embodiment may be used as a center information display (CID) located on an instrument panel, a center fascia, or a dashboard of a vehicle, a room mirror display replacing a side-view mirror of a vehicle, or a display located on the back of a front seat for entertainment for a back seat passenger of a vehicle.

The electronic device of the disclosure may be any of various devices. The electronic device may include at least one of a portable communication device (e.g., a smartphone), a computer device, a portable multimedia device, a portable medical device, a camera, a wearable device, and a home appliance. The electronic device according to an embodiment is not limited to the above devices.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims, and their equivalents.

What is claimed is:

1. A driving circuit comprising:
a plurality of stages configured to output gate signals to pixels, wherein
each of the plurality of stages comprises:
a first transistor connected between a first terminal configured to receive a start signal and a first node and comprising a gate connected to a second node;
a second transistor connected between a first clock terminal configured to receive a first clock signal and the second node and comprising a gate connected to a second terminal configured to receive a first voltage;
a third transistor connected between the first node and the second node;
a fourth transistor connected between a third node and a gate of the third transistor and comprising a gate connected to the second node;
a fifth transistor connected between the first node and the third node and comprising a gate connected to a third terminal configured to receive a second voltage; and
an output circuit configured to output the gate signal of a first level voltage or a second level voltage according to a voltage level of the second node and a voltage level of the third node.

2. The driving circuit of claim 1, wherein the start signal comprises an external signal or a gate signal output by a previous stage.

3. The driving circuit of claim 1, wherein the first transistor and the fifth transistor are P-type transistors and the second transistor, the third transistor, and the fourth transistor are N-type transistors.

4. The driving circuit of claim 1, wherein the output circuit comprises:
a sixth transistor connected between the second terminal and an output terminal and comprising a gate connected to the second node;
a seventh transistor connected between the output terminal and a second clock terminal configured to receive a second clock signal and comprising a gate connected to the third node; and
a capacitor connected between the third node and the output terminal.

5. The driving circuit of claim 4, wherein the sixth transistor and the seventh transistor are P-type transistors.

6. The driving circuit of claim 4, wherein
the first clock signal and the second clock signal are signals which alternate repeatedly the first level voltage and the second level voltage, and
the second clock signal being shifted by a half period with respect to the first clock signal.

7. The driving circuit of claim 6, wherein,
in a first section to which the start signal of the second level voltage, the first clock signal of the second level voltage, and the second clock signal of the first level voltage are input,
a voltage of the second node and a voltage of the third node are the second level voltage, and
the output terminal is configured to output an output signal of the first level voltage through the turned-on sixth transistor and the turned-on seventh transistor.

8. The driving circuit of claim 7, wherein,
in a second section which is subsequent to the first section and to which the start signal of the first level voltage, the first clock signal of the first level voltage, and the second clock signal of the first level voltage are input,
the voltage of the second node is the first level voltage, the voltage of the third node is the second level voltage, and
the output terminal is configured to output the output signal of the first level voltage through the turned-on seventh transistor.

9. The driving circuit of claim 8, wherein,
in a third section which is subsequent to the second section and to which the start signal of the first level voltage, the first clock signal of the first level voltage, and the second clock signal of the second level voltage are input,
the voltage of the second node is the first level voltage, the voltage of the third node is the third level voltage lower than the second level voltage, and
the output signal of the second level voltage is output from the output terminal through the turned-on seventh transistor.

10. The driving circuit of claim 9, wherein,
in a fourth section which is subsequent to the third section and to which the start signal of the first level voltage, the first clock signal of the first level voltage, and the second clock signal of the first level voltage are input,
the voltage of the second node is the first level voltage, the voltage of the third node is the second level voltage, and
the output signal of the first level voltage is output from the output terminal through the turned-on seventh transistor.

11. The driving circuit of claim 10, wherein,
in a fifth section which is subsequent to the fourth section and to which the start signal of the first level voltage, the first clock signal of the second level voltage, and the second clock signal of the first level voltage are input,
the voltage of the second node is the second level voltage, the voltage of the third node is the first level voltage, and
the output signal of the first level voltage is output from the output terminal through the turned-on sixth transistor.

12. The driving circuit of claim 1, wherein the first voltage is the first level voltage and the second voltage is the second level voltage.

13. A driving circuit comprising:
a plurality of stages configured to output gate signals to pixels, wherein
each of the plurality of stages comprises:
a first transistor connected between a first terminal configured to receive a start signal and a first node and comprising a gate connected to a second node;
a second transistor connected between a first clock terminal configured to receive a first clock signal and the second node and comprising a gate connected to a second terminal configured to receive a first voltage;
a third transistor connected between the first node and the second node;
a fourth transistor connected between the first node and a gate of the third transistor and comprising a gate connected to the second node; and
an output circuit configured to output the gate signal of a first level voltage or a second level voltage according to a voltage level of the first node and a voltage level of the second node.

14. The driving circuit of claim 13, wherein the output circuit comprises:
a fifth transistor connected between the second terminal and an output terminal and comprising a gate connected to the second node;
a sixth transistor connected between the output terminal and a second clock terminal configured to receive a second clock signal and comprising a gate connected to the first node; and
a capacitor connected between the first node and the output terminal.

15. The driving circuit of claim 14, wherein the first transistor, the fifth transistor, and the sixth transistor are P-type transistors and the second transistor, the third transistor, and the fourth transistor are N-type transistors.

16. The driving circuit of claim 14, wherein,
in a first section to which the start signal of the second level voltage, the first clock signal of the second level voltage, and the second clock signal of the first level voltage are input,
a voltage of the second node and a voltage of the third node are the second level voltage, and
an output signal of the first level voltage is output from the output terminal through the turned-on fifth transistor and sixth transistor.

17. The driving circuit of claim 16, wherein,
in a second section which is subsequent to the first section and to which the start signal of the first level voltage, the first clock signal of the first level voltage, and the second clock signal of the first level voltage are input,
the voltage of the first node is the second level voltage, the voltage of the second node is the first level voltage, and
the output signal of the first level voltage is output from the output terminal through the turned-on sixth transistor.

18. The driving circuit of claim 17, wherein,
in a third section which is subsequent to the second section and to which the start signal of the first level voltage, the first clock signal of the first voltage level, and the second clock signal of the second level voltage are input,
the voltage of the first node is the third level voltage lower than the second level voltage, the voltage of the second node is the first level voltage, and
the output signal of the second level voltage is output from the output terminal through the turned-on sixth transistor.

19. The driving circuit of claim 18, wherein,
in a fourth section which is subsequent to the third section and to which the start signal of the first level voltage, the first clock signal of the first level voltage, and the second clock signal of the first level voltage are input,
the voltage of the first node is the second level voltage, the voltage of the second node is the first level voltage, and
the output signal of the first level voltage is output from the output terminal through the turned-on sixth transistor.

20. The driving circuit of claim 19, wherein,
in a fifth section which is subsequent to the fourth section and to which the start signal of the first level voltage, the first clock signal of the second level voltage, and the second clock signal of the first level voltage are input,
the voltage of the first node is the first level voltage, the voltage of the second node is the second level voltage, and
the output signal of the first level voltage is output from the output terminal through the turned-on fifth transistor.

21. An electronic device comprising:
a controller configured to receive a signal from a processor and output a driving control signal; and
a driving circuit configured to receive the driving control signal, the driving circuit comprising a plurality of stages configured to output gate signals to pixels, wherein
each of the plurality of stages comprises:
a first transistor connected between a first terminal configured to receive a start signal and a first node and comprising a gate connected to a second node;
a second transistor connected between a first clock terminal configured to receive a first clock signal and the second node and comprising a gate connected to a second terminal to which a first voltage is supplied;
a third transistor connected between the first node and the second node;
a fourth transistor connected between a third node and a gate of the third transistor and comprising a gate connected to the second node;
a fifth transistor connected between the first node and the third node and comprising a gate connected to a third terminal configured to receive a second voltage; and
an output circuit configured to output the gate signal of a first level voltage or a second level voltage according to a voltage level of the second node and a voltage level of the third node.
